(19) United States
(12) Patent Application Publication
(10) Pub. No.: US 2024/0178055 A1
(43) Pub. Date: May 30, 2024

(54) INSULATING TRENCH MANUFACTURING

(71) Applicant: STMicroelectronics (Crolles 2) SAS, Crolles (FR)

(72) Inventors: Thierno Moussa BAH, Grenoble (FR); Pascal GOURAUD, Montbonnot St Martin (FR); Patrick GROS D'AILLON, Grenoble (FR); Emilie PREVOST, Grenoble (FR)

(73) Assignee: STMicroelectronics (Crolles 2) SAS, Crolles (FR)

(21) Appl. No.: 18/509,190

(22) Filed: Nov. 14, 2023

(30) Foreign Application Priority Data
Nov. 24, 2022 (FR) 2212257

(51) Int. Cl. H01L 21/762; H01L 21/02; H01L 21/306; H01L 21/768; H01L 29/94

(52) U.S. Cl. CPC H01L 21/76232; H01L 21/02164; H01L 21/02178; H01L 21/30617; H01L 21/30625; H01L 21/76831; H01L 29/945

(57) ABSTRACT

The present description concerns a method of manufacturing an insulating trench in a substrate, for an electronic device, comprising the following successive steps: (a) filling a trench formed in the substrate with a first insulating material; (b) depositing a first etch stop layer on the first material; (c) depositing a second layer of a second insulating material on the first etch stop layer; (d) etching down to the etch stop layer; and (e) depositing a third layer made of a third tight material.

### CROSS-REFERENCE TO RELATED APPLICATION(S)

This application claims the priority benefit of French patent application number FR2212257, filed on Nov. 24, 2022 entitled “Fabrication d'une tranchée isolante”, which is hereby incorporated by reference to the maximum extent allowable by law.

### BACKGROUND

### Technical Field

The present disclosure generally concerns electronic and microelectronic devices and components. The present disclosure more particularly concerns the manufacturing of these electronic devices and components and more precisely the forming of electrical insulation or optical insulation trenches.

### Description of the Related Art

Electronic and microelectronic device and component manufacturing methods evolve constantly. It is current to use insulating trenches to electrically and optically insulate a component from one or a plurality of other neighboring components, or even to electrically or optically insulate a plurality of portions of a same electric component.

### BRIEF SUMMARY

An embodiment overcomes all or part of the disadvantages of known methods of manufacturing insulating trenches.

An embodiment provides a method of manufacturing an insulating trench in a substrate, for an electronic device, comprising the following successive steps:
(a) filling a trench formed in said substrate with a first insulating material;
(b) depositing a first etch stop layer on said first material;
(c) depositing a second layer of a second insulating material on said first etch stop layer;
(d) etching down to the etch stop layer; and
(e) depositing a third layer made of a third tight material.

According to an embodiment, the third material is waterproof.

According to an embodiment, the method further comprises, between step (a) and (b), a step (f) of polishing of the surface of said substrate.

According to an embodiment, step (f) implements a chemical-mechanical polishing method.

According to an embodiment, the method further comprises, between step (f) and (b), a wet etching step (g).

According to an embodiment, during step (g), the wet etching uses a hydrofluoric acid solution.

According to an embodiment, step (d) is an anisotropic etching step.

According to an embodiment, the first etch stop layer is a layer of aluminum oxide or aluminum nitride.

According to an embodiment, the first etch stop layer has a thickness in the range from 5 to 20 nm.

According to an embodiment, the second layer has a thickness greater than or equal to half a diameter of a still empty portion of said trench after filling step (a).

According to an embodiment, the second insulating material is silicon oxide.

According to an embodiment, the third tight material is aluminum oxide.

According to an embodiment, the third layer made of the third tight material has a thickness in the range from 5 to 20 nm.

Another embodiment provides a method of manufacturing a capacitor using the previously-described method.

Another embodiment provides a tight insulating trench, for an electronic device, comprising an insulating trench having a central cavity filled with a stack successively comprising:
a first etch stop layer;
a second layer of a second insulating material; and
a third layer made of a third tight material.

Another embodiment provides a tight capacitor comprising a previously-described insulating trench.

Another embodiment provides an image sensor comprising a previously-described insulating trench.

Another embodiment provides an image sensor comprising a previously-described capacitor.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows a cross-section view of an insulating trench;

FIG. 2 schematically shows a cross-section view of an insulating trench used to form a capacitor;

FIGS. 3(A)-3(E) shows five cross-section views illustrating an implementation mode of a method of manufacturing an insulating trench; and

FIG. 4 shows a cross-section view of an embodiment of an image sensor.

### DETAILED DESCRIPTION

Like features have been designated by like references in the various figures. In particular, the structural and functional features that are common among the various embodiments may have the same references and may dispose identical structural, dimensional and material properties.

For the sake of clarity, only the steps and elements that are useful for the understanding of the described embodiments have been illustrated and described in detail. In particular, the possible uses of insulating trenches obtained by the implementation modes described hereafter are not detailed, current uses in electronic devices being compatible.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

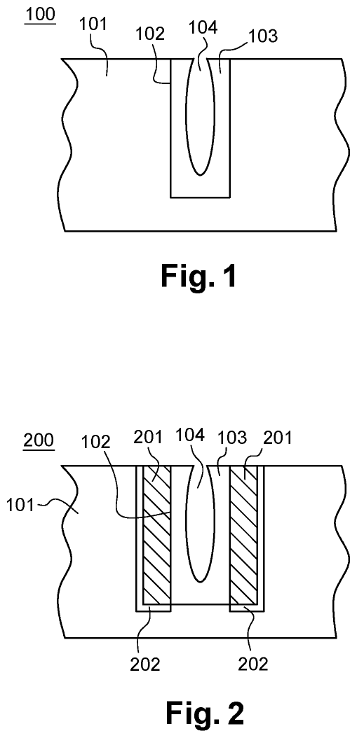

FIG. 1 is a cross-section view showing an insulating trench 100.

Insulating trench 100 is formed in a substrate 101 from a trench 102 filled with an insulating material 103. Trench 102 extends from the surface of substrate 101. According to an example, the substrate may be a semiconductor substrate, for example a substrate comprising silicon. Trench 102 may have a width in the range from 200 to 400 nm, for example in the order of 300 nm, and may have a depth in the range from 3 to 10 μm, for example in the order of 6 μm. According to an example, insulating material 103 is silicon oxide (SiO2).

To manufacture insulating trench 100, trench 102 is formed in substrate 101, for example by using an etching method. Trench 101 is then filled with insulating material 103 by using a step of deposition of a layer of said insulating material, generally, a step of conformal deposition.

A problem regularly occurring is that a central portion of the trench may not be filled during this deposition step, and insulating trench 100 may exhibit, at the end of its manufacturing process, an empty cavity 104, or empty portion 104, positioned at the level of the center of the insulating trench. The presence of such a cavity may result in tightness problems at the level of the insulating trench.

According to an example, an insulating trench of the type of trench 100 may be used to delimit the periphery of a simple electronic device, such as a transistor, or of a more complex electronic device, such as a pixel. According to another example, an insulating trench of this type may be used within an electronic device.

FIG. 2 is a cross-section view showing a capacitor 200.

Capacitor 200 has elements common with the insulating trench 100 described in relation with FIG. 1. These common elements are not described in detail again, and only the differences between capacitor 200 and insulating trench 100 are highlighted hereafter.

Capacitor 200 is formed like the insulating trench, and further exhibits two electrically-conductive electrodes 201 placed on either side of trench 103. Electrodes 201 are generally formed against the walls of a trench formed in a substrate, after which the rest of the trench is filled with an insulating material, in the same way as trench 101 is filled with material 103. According to an example, electrodes 201 are electrically insulated from substrate 101 by an electrically-insulating layer 202.

The problem discussed in relation with FIG. 1 may very well occur during the manufacturing of capacitor 200. Indeed, a central portion of trench 101 may not be filled during this deposition step, and capacitor 200 may exhibit, at the end of this manufacturing method, the empty cavity 104 described in relation with FIG. 1. The presence of such a cavity may result in tightness problems at the level of the insulating trench.

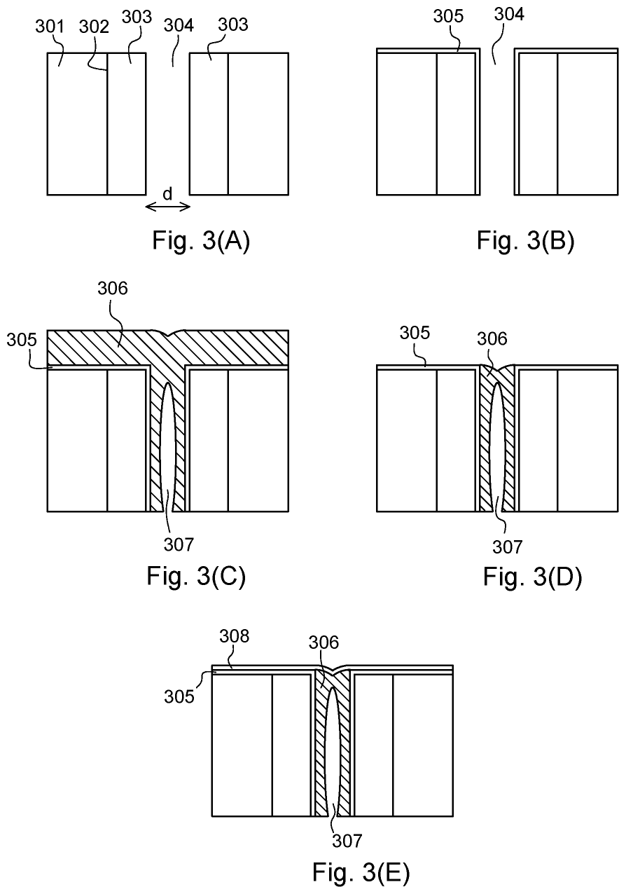

FIGS. 3(A)-3(E) shows an implementation mode of a method of manufacturing an insulating trench, or a capacitor 200, enabling to reduce the forming of cavity 104. FIGS. 3(A)-3(E) more particularly comprises five cross-section views illustrating steps of an implementation mode of the method of manufacturing an insulating trench overcoming the problem described in relation with FIG. 1.

At FIG. 3(A), an insulating trench of the type of the insulating trench 100 of FIG. 1 has been formed. In other words, a trench 302 has been formed in a substrate 301, then has been filled with an insulating material 303. A cavity 304 of the type of cavity 104 is still present after the filling step.

According to an example, substrate 301 is a semiconductor substrate, comprising, for example, silicon. According to an example, trench 302 may have a width in the range from 200 to 300 nm, for example in the order of 220 nm, and may have a depth in the range from 1 to 10 μm, for example in the order of 3 μm. According to an example, insulating material 303 is silicon oxide (SiO2). Cavity 304 has a maximum diameter noted d.

Further, at FIG. 3(A), and optionally, a polishing method has been implemented. This polishing step enables to update cavity 304 on the side of the surface of substrate 301. According to an example, the polishing method is a chemical-mechanical polishing (CMP).

Further, and optionally, an additional cleaning step may be implemented after the polishing method. This cleaning step is, for example, the implementation of a wet etching method. for example using hydrofluoric acid.

At FIG. 3(B), subsequent to FIG. 3(A), an etch stop layer 305 is conformally deposited on the structure of FIG. 3(A). An etch stop layer is a layer made of a material having a slower etching speed than the speed of etching of another material deposited afterwards, all or part of which is intended to be etched. According to an example, etch stop layer 305 is a layer of an electrically-insulating material such as, for example, aluminum oxide (Al2O3), or aluminum nitride (AlN). Etch stop layer 305 has a thickness in the range from 5 to 20 nm, for example in the order of 7 nm.

At FIG. 3(C), subsequent to FIG. 3(B), a layer 306 made of an insulating material is deposited on top of, and in contact with, etch stop layer 305. According to an example, the insulating material of layer 306 is silicon oxide (SiO2). According to an embodiment, the speed of etching of the material of layer 306 is greater than the speed of etching of the material of layer 305. According to an example, the insulating material of layer 306 is the same material as that of layer 303. According to another example, the insulating material of layer 306 is different from material 303. Layer 306 has a thickness greater than or equal to half the diameter of cavity 304.

Layer 306 enables to fill the cavity 304 left empty after the filling of trench 302, and enables to close the inlet of cavity 304. According to an example, a cavity 307 may still be present even after the deposition of layer 306.

At FIG. 3(D), subsequent to FIG. 3(C), an etching method, for example an anisotropic etching method, is implemented. The etching method is implemented to reach etch stop layer 305, and thus enables to remove the portions of layer 306 resting outside of cavity 304, like the portion of layer 304 resting at the level of the surface of substrate 301. This operation is carried out without the use of a mask. According to an example, the etching method may be a plasma etching, or a dry etching.

At FIG. 3(E), subsequent to FIG. 3(D), a layer 308 made of a tight, scaling material, for example one that is waterproof (water impermeable), is conformally deposited on the structure of FIG. 3(D). According to an example, layer 308 is an aluminum oxide (Al2O3) layer. Layer 308 has a thickness in the range from 5 to 20 nm, for example in the order of 7 nm. According to an example, layer 308 may also be used as a charge passivation layer.

An advantage of this embodiment is that it enables to fill, at least partly, the cavity 304 formed during the manufacturing, and to make the insulating trench tight, for example waterproof.

According to an embodiment, other steps of manufacturing of electronic devices may be interposed between FIG. 3(C) and 3(D). In particular, FIG. 3(D) and 3(E) may be carried out at the end of a method of manufacturing an electronic device comprising insulating trenches having a manufacturing method comprising steps similar to Figured 3(A) to 3(C). In this case, FIG. 3(D) and 3(E) are used as a step of a method of correction of defects that may appear during the manufacturing of one or a plurality of insulating trenches.

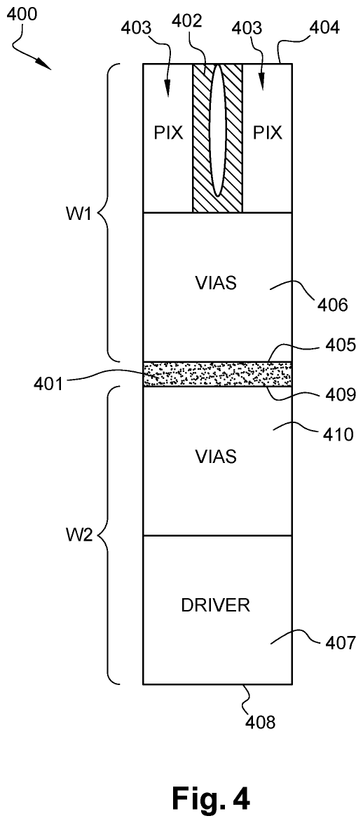

FIG. 4 is a cross-section view illustrating an embodiment of an image sensor 400 comprising an insulating trench obtained by the method described in relation with FIGS. 3(A)-3(E).

Image sensor 400 comprises two semiconductor substrates W1 and W2 bonded to each other via a connection interface 401.

At the level of substrate W1, image sensor 400 comprises an insulating trench 402 and one or a plurality of components of image sensor 403 (PIX), for example one or a plurality of pixels. More particularly, component(s) 403 and insulating trench 402 extend from an upper surface 404 of substrate W1. Insulating trench 402 is used to electrically and optically insulate component(s) 403 from one another. Between a lower surface 405 of substrate W1, opposite to the upper surface 404 of substrate W1, and a lower surface of components 403 and of insulating trench 402, substrate W1 comprises a connection network 406 (VIAS).

At the level of substrate W2, image sensor 400 comprises a circuit 407 (DRIVER) for driving component 403. Driver circuit 407 comprises, for example, a network of transistors. Driver circuit 407 extends from a lower surface 408 of substrate W2, all over a portion of substrate W2, or, for example, across the entire thickness of substrate W2. Between a lower surface 409 du substrate W2, opposite to the upper surface 408 of substrate W2, and a lower surface of circuit 407, substrate W2 comprises a connection network 410 (VIAS).

An example of a method of manufacturing image sensor 400 comprises the following successive steps:
manufacturing of component 403 in substrate W1, comprising the implementation of the method described in relation with FIGS. 3(A)-3(E) to obtain insulating trench 402;
manufacturing of circuit 406 in substrate W2; and
fastening, for example by bonding, of the lower surface 405 of substrate W1 to the upper surface 409 of substrate W2.

Connection networks 406 and 410 and connection interface 401 enable to electrically connect component(s) 403 with driver circuit 407.

An advantage of using the manufacturing method of FIGS. 3(A)-3(E) is that it enables to obtain an image sensor having an insulating trench which is effectively tight. Indeed, during the manufacturing of component 403 and of trench 402, a cavity of the type of the cavity 104 described in relation with FIG. 1 may appear. The use of the method of FIGS. 3(A)-3(E) enables to close this cavity.

Various embodiments and variants have been described. Those skilled in the art will understand that certain features of these various embodiments and variants may be combined, and other variants will occur to those skilled in the art. In particular, the method of FIGS. 3(A)-3(E) may be applied to other manufacturing methods, such as, for example, to the method of forming a capacitor of the type of the capacitor 200 of FIG. 2. Further, the insulating trench 402 of image sensor 400 may be replaced with a capacitor obtained by the method described in relation with FIGS. 3(A)-3(E).

Finally, the practical implementation of the described embodiments and variants is within the abilities of those skilled in the art based on the functional indications given hereabove.

Method of manufacturing an insulating trench in a substrate (301), for an electronic device, may be summarized as including the following successive steps: (a) filling a trench (302) formed in said substrate (301) with a first insulating material (303); (b) depositing a first etch stop layer (305) on said first material (303); (c) depositing a second layer (306) of a second insulating material on said first etch stop layer (305); (d) etching down to the etch stop layer (305); and (e) depositing a third layer made of a third tight material (308).

The third material (308) may be waterproof.

Method may further include, between step (a) and (b), a step (f) of polishing of the surface of said substrate (301).

Step (f) may implement a chemical-mechanical polishing method.

Method may include, further, between step (f) and (b), a wet etching step (g).

During step (g), the wet etching may use a hydrofluoric acid solution.

Step (d) may be an anisotropic etching step.

The first etch stop layer (305) may be a layer of aluminum oxide or aluminum nitride.

The first etch stop layer (305) may have a thickness in the range from 5 to 20 nm.

The second layer (306) may have a thickness greater than or equal to half a diameter of a still empty portion (304) of said trench (301) after the filling step (a).

The second insulating material (306) may be silicon oxide.

The third tight material (308) may be aluminum oxide.

The third layer made of the third tight material (308) may have a thickness in the range from 5 to 20 nm.

Method of manufacturing a capacitor may use the method according to claim 1.

Tight insulating trench, for an electronic device, may be summarized as including an insulating trench having a central cavity (304) filled with a stack successively comprising: a first etch stop layer (305); a second layer (306) of a second insulating material; and a third layer made of a third tight material (308).

Tight capacitor may be summarized as including an insulating trench according to claim 15.

Image sensor may be summarized as including an insulating trench according to claim 15.

Image sensor may be summarized as including a capacitor according to claim 16.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming an insulating trench in a substrate, for an electronic device including:
filling a trench in the substrate with a first insulating material;
forming a first etch stop layer on the first material;
forming a second layer of a second insulating material on the first etch stop layer;
etching down to the etch stop layer; and
forming a third layer of a third trench sealing material.

2. The method according to claim 1, wherein the third material is waterproof.

3. The method according to claim 1, comprising polishing of the surface of the substrate before forming the first etch stop layer.

4. The method according to claim 3, wherein polishing the surface includes chemical-mechanical polishing.

5. The method according to claim 3, comprising wet etching before polishing the surface of the substrate.

6. The method according to claim 5, wherein the wet etching includes using a hydrofluoric acid solution.

7. The method according to claim 1, wherein etching down includes anisotropic etching.

8. The method according to claim 1, wherein the first etch stop layer is a layer of aluminum oxide or aluminum nitride.

9. The method according to claim 1, wherein the first etch stop layer has a thickness in the range from 5 to 20 nm.

10. The method according to claim 1, wherein the second layer has a thickness greater than or equal to half a diameter of a still empty portion of the trench after the filling.

11. The method according to claim 1, wherein the second insulating material is silicon oxide and the third trench sealing material is aluminum oxide.

12. A method, comprising:
forming a trench in a substrate
filling the trench a first insulating material;
forming a first etch stop layer on the first insulating material;
forming a second layer of a second insulating material on the first etch stop layer;
forming a planarized surface by chemical mechanical polishing down to the first etch stop layer; and
forming a third layer of a third trench sealing material on the planarized surface.

13. The method according to claim 12, wherein the third layer has a thickness in the range from 5 to 20 nm.

14. The method according to claim 13, comprising chemical mechanical polishing the substrate and the trench before forming the first etch stop layer.

15. A device, comprising:
a substrate having a first surface;
a trench in the substrate, the trench having:
a central cavity;
a first insulating layer in the cavity;
a stack in the central cavity, the stack includes:
a first etch stop layer on the first insulating layer in the trench and on the first surface of the substrate;
a second layer of a second insulating material in the trench, on the first etch stop layer and on the first surface of the substrate; and
a third layer of a third sealing material on the second layer, on the trench, and on the first surface of the substrate.

16. The device of claim 15, comprising a capacitor that includes the trench.

17. The device of claim 15, comprising an image sensor that includes trench.

18. The device of claim 16, comprising an image sensor that includes the capacitor that includes the trench.
